(19) United States
(12) Patent Application Publication
(10) Pub. No.: US 2010/0141100 A1
(43) Pub. Date: Jun. 10, 2010

(54) Method of manufacturing piezoelectric oscillating pieces, piezoelectric oscillating piece, and piezoelectric resonator

(75) Inventors: Takehiro Takahashi, Sayama-shi (JP); Masahiro Yoshimatsu, Sayama-shi (JP)

Correspondence Address: JORDAN AND HAMBURG LLP, 122 EAST 42ND STREET, SUITE 4000, NEW YORK, NY, 10168, US

(73) Assignee: NIHON DEMPA KOGYO CO., LTD., Shibuya-ku (JP)

(21) Appl. No.: 12/592,623

(22) Filed: Nov. 30, 2009

(30) Foreign Application Priority Data
Dec. 5, 2008 (JP) 2008-311419

(51) Int. Cl. H01L 41/047; H01L 41/22

(52) U.S. Cl. 310/365; 29/25.35

(57) ABSTRACT

Wafer-level processing of making outer peripheral ends (beveled portions) of piezoelectric oscillating pieces thinner than center portion sides is made possible easily and at low cost. A metal film which is a mask of a piezoelectric substrate and a photoresist film which is a mask of the metal film and has a pattern with which connection support portions supporting piezoelectric oscillating pieces on the piezoelectric substrate are formed are stacked on the piezoelectric substrate in this order from the substrate side, and by etching with the photoresist film and the metal film used as masks, contours of the plural piezoelectric oscillating pieces are formed in the piezoelectric substrate. Then, from a direction of through spaces (side surfaces) formed by this etching, the metal film is etched with an etching solution without peeling off the photoresist film, whereby outer peripheral sides of the metal film are removed and surfaces of outer peripheral ends of the piezoelectric oscillating pieces are exposed, and the exposed surfaces are etched with an etching solution, whereby the piezoelectric oscillating pieces are processed so that outer peripheral ends thereof become thinner than inner peripheral sides.

### BACKGROUND OF THE INVENTION

1. Field of the Invention

The present invention relates to a method of manufacturing piezoelectric oscillating pieces made of, for example, quartz crystal or the like, a piezoelectric oscillating piece manufactured by this method, and a piezoelectric unit including the piezoelectric oscillating piece.

2. Description of the Related Art

An element for quartz-crystal unit is structured such that, for example, electrodes for excitation (excitation electrodes) are formed on an upper surface and a lower surface of a quartz-crystal piece (quartz-crystal blank), and has a characteristic that crystal oscillation is excited by an inverse piezoelectric effect that occurs in a quartz crystal when a voltage is applied to the excitation electrodes. For example, the element for quartz-crystal unit is housed in a package for protection and the package is manufactured as a quartz-crystal unit, which is widely used in electronic components such as oscillators as a reference source of frequency or time.

In recent years, there is a strong demand for a quartz-crystal unit with a smaller CI value (crystal impedance), and for this purpose, there has been used a quartz-crystal unit including a quartz-crystal oscillating piece (element) whose outer peripheral end is worked (beveled) to be thinner than an inner peripheral (center) side being an excitation portion, in order to confine oscillation energy in the excitation portion. In this beveling, the shape of the outer peripheral end (size and thinness of a beveled portion) is adjusted according to the size of the quartz-crystal oscillating piece, a frequency band used, and so on so that the element has a necessary characteristic.

As a method of such beveling, there has been known a method, for example, in which after a quartz-crystal substrate is divided into a plurality of individual chips (piezoelectric oscillating pieces), these chips together with an abrasive and so on are put into, for example, a polishing vessel and for example, the polishing vessel is rotated around a vertical axis so that outer peripheral ends of the chips and the abrasive rub against each other due to the own weight of the chips, whereby the outer peripheral ends of the chips are worked into a tapered shape. This method, however, uses the weight of the chips for working and thus requires a longer working time as the chips are smaller (lighter). Further, if the tapering comes after separating the quartz-crystal oscillating pieces into chips, in order to thereafter form metal electrodes on these quartz-crystal oscillating pieces, processing such as, is for example, sputtering for forming a metal film has to be performed separately for each of the chips. This requires an extremely great labor (manhours).

Under such circumstances, a technique for realizing wafer-level beveling has been considered. Concretely, there has been considered a method in which a plurality of stepped portions are formed at outer peripheral ends of quartz-crystal oscillating pieces so that the quartz-crystal oscillating pieces become gradually thinner from an inner peripheral side toward an outer peripheral side. In this method, first, for example, a resist film which is patterned so that peripheries of chips are etched and the chips are cut out is formed on a quartz-crystal substrate (wafer), and with the resist film used as a mask, the quartz-crystal substrate is slightly etched. By this etching, shallow grooves are formed in the quartz-crystal substrate along contours of the quartz-crystal oscillating pieces. Then, the resist film is peeled off, and a resist film having patterns whose contours are slightly smaller than the grooves in the quartz-crystal substrate is formed on the quartz-crystal substrate. When the quartz-crystal substrate is next slightly etched with this resist film used as a mask, whole areas including the grooves formed by the first etching are slightly removed, so that stepped portions whose inner side is slightly higher than an outer side are formed all along a circumferential direction in the areas (grooves) corresponding to the outer peripheral ends of the quartz-crystal oscillating pieces.

Thereafter, the formation of a resist film having patterns slightly smaller than the contours of the grooves and the etching of the quartz-crystal substrate by using the resist film as a mask are repeated a predetermined number of times, so that a plurality of stepped portions which become gradually thinner (lower) toward the outer peripheral side are formed on the outer peripheral ends (beveled portions) of the quartz-crystal oscillating pieces. Then, after excitation electrodes made of metal are formed on the quartz-crystal oscillating pieces on the substrate, the quartz-crystal oscillating pieces (chips) are separated to individual pieces by, for example, etching. By thus processing the outer peripheral ends of the quartz-crystal oscillating pieces at the wafer level, it is possible to obtain the quartz-crystal oscillating pieces having favorable CI values easily and at low cost. However, the formation of the resist film requires processes such as, for example, a coating process of resist solutions, an exposure process, and a development process and thus still requires a lot of manhours. Therefore, there has been a demand for a technique for further reducing manhours and obtaining quartz-crystal oscillating pieces easily and at low cost.

Patent document 1 describes a technique in which a plurality of layers of photoresist films whose end portions are inclined in a tapered manner are formed on a quartz-crystal substrate and outer peripheral ends of quartz-crystal oscillating pieces are tapered at a wafer level by using the photoresist film. However, in this technique, the formation of the photoresist film needs to be repeated a plurality of times, leading to a lot of manhours.

Patent document 2 describes a technique in which a photoresist film with convex surfaces is formed on a quartz-crystal substrate and R surfaces are formed on surfaces of quartz-crystal oscillating pieces, but it is extremely difficult to form the plural convex surfaces in the photoresist film with high accuracy.

[Patent Document 1] Japanese Patent Application Laid-open No. 2007-97046 (0023) to (0025), FIG. 2)

[Patent Document 2] Japanese Patent Application Laid-open No. 2005-244677 ((0017) to (0021))

### SUMMARY OF THE INVENTION

The present invention was made under such circumstances and has an object to provide a method of manufacturing piezoelectric oscillating pieces realizing, easily and at low cost, the wafer-level formation of a plurality of piezoelectric oscillating pieces whose outer peripheral ends are formed thinner than inner peripheral sides, and to provide a piezoelectric oscillating piece manufactured by this method, and a piezoelectric unit including the piezoelectric oscillating piece.

A method of manufacturing piezoelectric oscillating pieces of the present invention includes:

forming a metal film on a surface of a piezoelectric substrate which is cut in a manner that an etching rate in a thickness direction becomes higher than an etching rate in a plane direction (a);

forming a photoresist film on a surface of the metal film, the photoresist film having a pattern with which areas around the piezoelectric oscillating pieces are etched and connection support portions supporting the piezoelectric oscillating pieces are formed between the piezoelectric oscillating pieces and the piezoelectric substrate (b);

etching the metal film by using the photoresist film as a mask, to form a pattern (c);

next, etching the piezoelectric substrate by using the photoresist film and the metal film as masks, to form contours of the piezoelectric oscillating pieces corresponding to the pattern on the piezoelectric substrate (d);

subsequently, from a direction of through spaces formed by the etching for forming the contours of the piezoelectric oscillating pieces, etching the metal film with an etching solution without peeling off the photoresist film, to remove outer peripheral sides of the metal film and expose surfaces of outer peripheral ends of the piezoelectric oscillating pieces (e); and

thereafter, etching the exposed surfaces of the piezoelectric substrate with an etching solution in the thickness direction of the piezoelectric substrate so as to make the outer peripheral ends of the piezoelectric oscillating pieces thinner than inner peripheral sides of the piezoelectric oscillating pieces (f).

Preferably, the exposing the surfaces of the outer peripheral ends of the piezoelectric oscillating pieces (e) and the etching (f) are repeated at least once after the etching (f).

Preferably, the method further includes after the etching (f): forming electrodes on surfaces of the piezoelectric oscillating pieces by peeling off the photoresist film and the metal film; and obtaining the plural piezoelectric oscillating pieces from the piezoelectric substrate by removing the connection support portions.

Preferably, the piezoelectric substrate is an AT-cut quartz-crystal substrate.

A piezoelectric oscillating piece of the present invention is a piezoelectric oscillating piece manufactured by the above-described method of manufacturing the piezoelectric oscillating pieces.

A piezoelectric unit of the present invention includes: the above-described piezoelectric oscillating piece; a vessel housing the piezoelectric oscillating piece; and an external electrode electrically connected to the electrode of the piezoelectric oscillating piece.

In the present invention, in manufacturing a plurality of piezoelectric oscillating pieces whose outer peripheral ends are formed thinner than inner peripheral sides at a wafer level, the metal film and the photoresist film are stacked on the piezoelectric substrate in this order from the piezoelectric substrate side, the metal film being is a mask of the piezoelectric substrate, and the photoresist film being a mask of the metal film and having the pattern with which the connection support portions connecting the piezoelectric oscillating pieces and the piezoelectric substrate are formed to prevent the piezoelectric oscillating pieces from coming off from the piezoelectric substrate after the etching, and the etching is performed with the photoresist film and the metal film used as masks, whereby the contours of the plural piezoelectric oscillating pieces are formed in the piezoelectric substrate. Then, from the direction of the through spaces (side surfaces) formed by the etching for forming the contours of the piezoelectric oscillating pieces, the metal film is etched with the etching solution without peeling off the photoresist film, whereby the outer peripheral sides of the metal film are removed and the surfaces of the outer peripheral ends of the piezoelectric oscillating pieces are exposed, and the exposed surfaces are etched with the etching solution in the thickness direction of the piezoelectric substrate so that the outer peripheral ends of the piezoelectric substrate becomes thinner than the inner peripheral side. Therefore, since the outer peripheral ends of the piezoelectric oscillating pieces can be made thinner than the inner peripheral side at a wafer level, it is possible to obtain the plural piezoelectric oscillating pieces easily and at low cost.

### BRIEF DESCRIPTION OF THE DRAWINGS

FIG. 1 is a plane view illustrating an example of a piezoelectric substrate in which quartz-crystal oscillating pieces according to an embodiment of the present invention are to be formed;

FIG. 2(a) to FIG. 2(c) are schematic views illustrating an example of a method of manufacturing the quartz-crystal oscillating pieces;

FIG. 3(a) to FIG. 3(c) are schematic views illustrating an example of the method of manufacturing the quartz-crystal oscillating pieces;

FIG. 4(a) to FIG. 4(c) are schematic views illustrating an example of the method of manufacturing the quartz-crystal oscillating pieces;

FIG. 5(a) and FIG. 5(b) are schematic views illustrating an example of the method of manufacturing the quartz-crystal oscillating pieces;

FIG. 6 is a plane view illustrating an example of a pattern of a photoresist film used for forming the quartz-crystal oscillating pieces;

FIG. 7(a) to FIG. 7(e) are schematic views illustrating an example of the method of manufacturing the quartz-crystal oscillating pieces;

FIG. 8 is a plane view illustrating the piezoelectric oscillating pieces formed in the substrate;

FIG. 9(a) and FIG. 9(b) are perspective views illustrating the piezoelectric oscillating piece;

FIG. 10(a) and FIG. 10(b) are schematic views illustrating another example of the method of manufacturing the piezoelectric oscillating pieces;

FIG. 11(a) and FIG. 11(b) are schematic views illustrating the other example of the method of manufacturing the piezoelectric oscillating pieces; and

FIG. 12(a) and FIG. 12(b) are schematic views illustrating a quartz-crystal unit including the piezoelectric oscillating piece.

### DETAILED DESCRIPTION OF THE PREFERRED EMBODIMENT

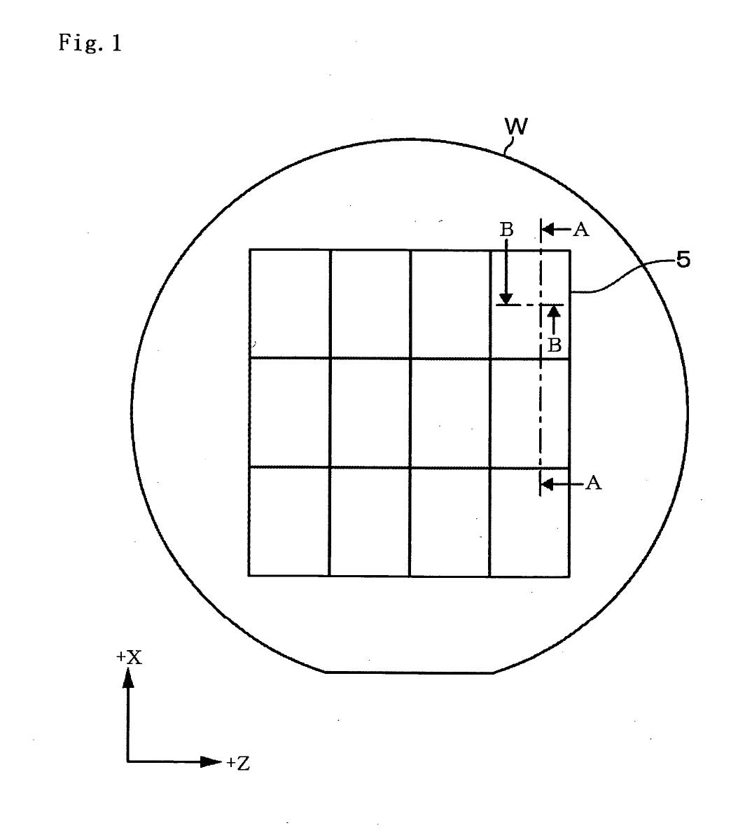

A method of manufacturing piezoelectric oscillating pieces of an embodiment of the present invention will be described with reference to FIG. 1 to FIG. 9(b). In this embodiment, in manufacturing a quartz-crystal oscillating piece 1 being the piezoelectric oscillating piece, a plurality of the quartz-crystal oscillating pieces 1 on whose surfaces later-described electrodes 50 to 53 are formed are cut out (cut into chips) from a wafer W being a piezoelectric (quartz-crystal) substrate, for instance. Concretely, as illustrated in FIG. 1, sectional areas 5 which will be formation areas of the quartz-crystal oscillating pieces 1 are arranged in grid laterally and vertically at a plurality of places, for example, at 30 places on the wafer W which is formed (cut) so as to be an AT-cut plate. This AT-cut plate is a wafer W which is cut at, for example, a 30° 15′+α crystal orientation (α: differs depending on the specification of each of the piezoelectric oscillating pieces) from a Z axis.

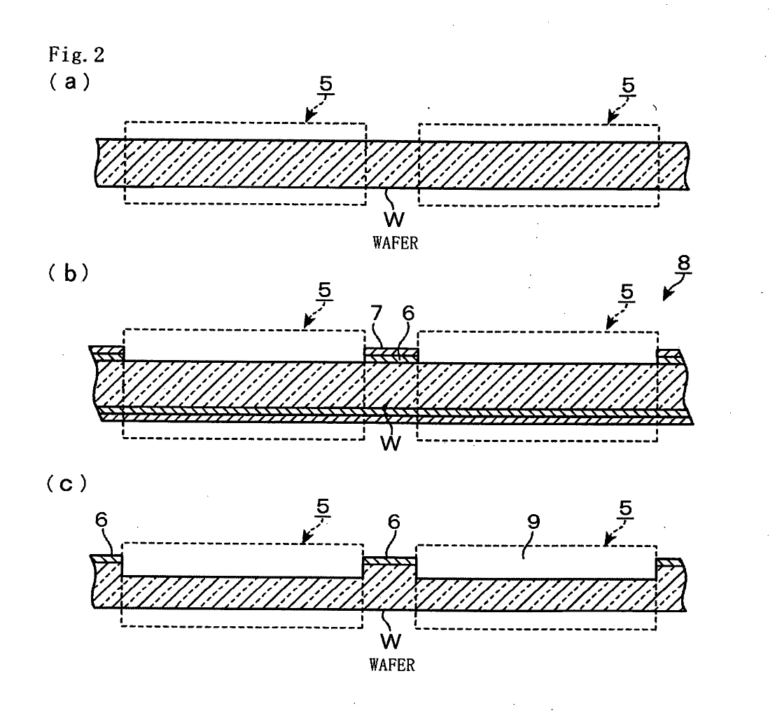

The sectional areas 5 are formed on the wafer W illustrated in FIG. 2(a) as follows, for instance. First, a metal film 6 and a resist film 7 made of Cr (chromium) and gold (Au) are formed on each of a front surface and a rear surface (upper and lower surfaces) of the wafer W in this order from a wafer W side. Then, as illustrated in FIG. 2(b), a pattern 8 is formed in the resist film 7 on the front surface side of the wafer W by an exposure process and a development process and the metal film 6 is etched while the wafer W is immersed in a potassium iodide (KI) aqueous solution. Then, the wafer W is immersed in a hydrofluoric acid (HF) aqueous solution to be etched, whereby concave portions 9 are formed in the respective sectional areas 5 as illustrated in FIG. 2(c). Thereafter, the resist films 7 on the upper and lower surfaces are peeled off and the metal film 6 on the rear surface is removed. Note that FIG. 2(a) to FIG. 2(c) schematically illustrate a vertical section of the wafer W taken along A-A line in FIG. 1(a).

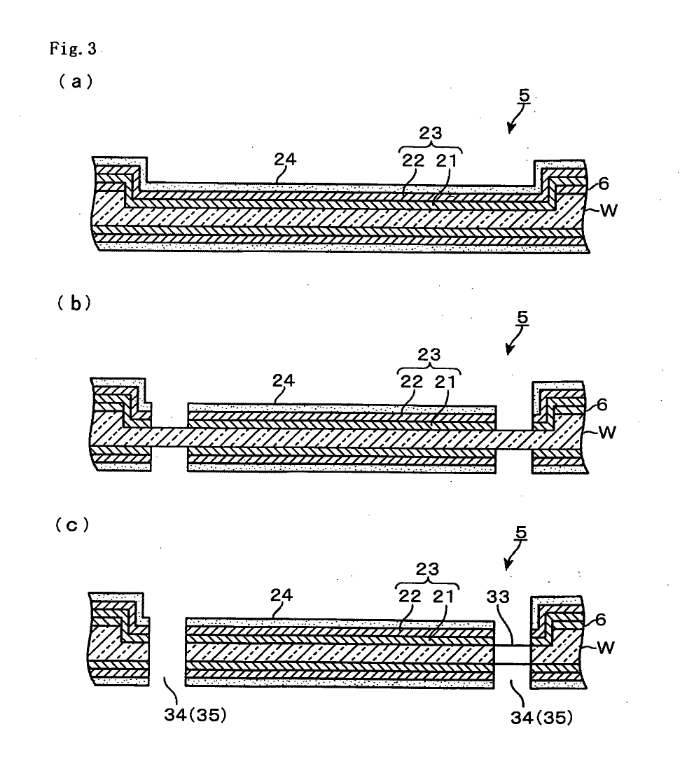

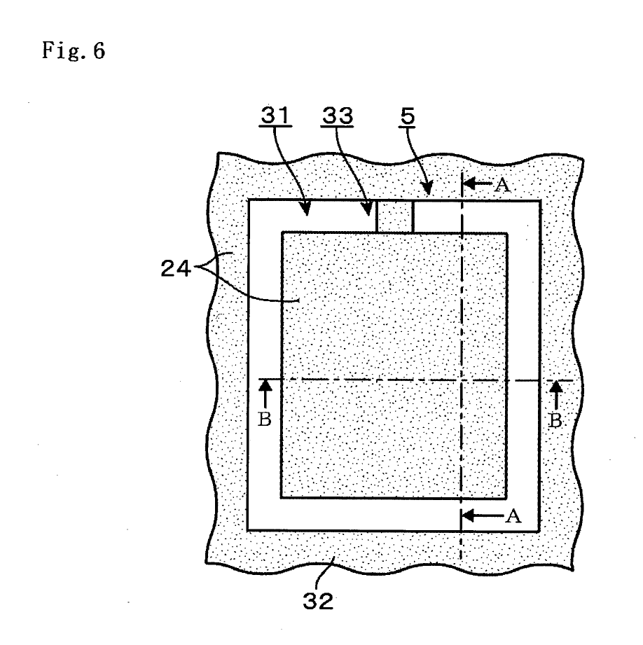

Next, as illustrated in FIG. 3(a), a lower layer film 21 made of chromium or the like and an upper layer film 22 made of metal or the like are stacked on each of the upper and lower surfaces in this order from the wafer W side by, for example, a sputtering method to form metal films 23 being film stacks each composed of the films 21, 22. Further, photoresist films 24 are formed on the upper and lower surfaces of the wafer W, and by an exposure process and a development process of the photoresist films 24, the photoresist films 24 are patterned so that, for example, rectangular patterns 31 corresponding to the quartz-crystal oscillating pieces 1 are formed on the respective sectional areas 5 as illustrated in FIG. 6. In each of the patterns 31, in order to prevent the quartz-crystal oscillating piece 1 from coming off the wafer W during the etching, an area where a connection support portion 33 holding the quartz-crystal oscillating piece 1 is to be formed is formed by patterning between a frame portion 32 surrounding the quartz-crystal oscillating piece 1 and an end portion of the quartz-crystal oscillating piece 1. In FIG. 6, the photoresist film 24 is hatched for easier view of the drawing.

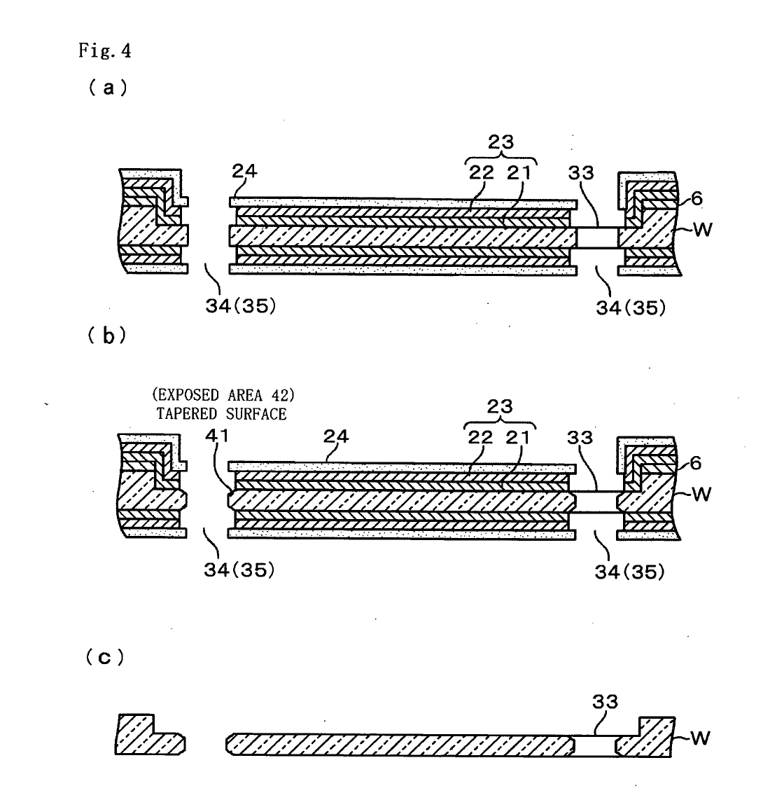

Next, the wafer W is immersed in, for example, a potassium iodide aqueous solution being a metal etching solution, and as illustrated in FIG. 3(b), the metal films 23 are etched with the photoresist films 24 used as masks so that the metal films 23 have the shapes corresponding to the aforesaid patterns 31. Subsequently, the wafer W is immersed in, for example, a hydrofluoric acid aqueous solution being an etching solution, and as illustrated in FIG. 3(c), the wafer W is etched with the photoresist films 24 and the metal films 23 used as masks so as to have the shapes corresponding to the patterns 31. By this etching, concave portions 34, 34 bored in the wafer W from the upper and lower surfaces communicate with each other, whereby through spaces 35 are formed, the contours of the quartz-crystal oscillating pieces 1 are formed, and one-side ends of the quartz-crystal oscillating pieces 1 are supported on the wafer W (frame portions 32) via the connection support portions 33. Note that the single sectional area 5 is illustrated in FIG. 3(a) to FIG. 3(c) and FIG. 4(a) to FIG. 4(c).

Then, when the wafer W is immersed again in the aforesaid potassium iodide aqueous solution for a predetermined time, the metal films 23 seen from a direction of the through spaces 35 (side surface) come into contact with the aqueous solution, while the photoresist films 24 are left on the surfaces of the metal films 23 without peeled off, as illustrated in FIG. 4(a), and consequently, the metal films 23 are eroded from a side direction, so that outer peripheral sides of the metal films 23 are removed (etched) by a predetermined dimension. At this time, portions, of the metal films 23, connected to the aforesaid connection support portions 33 hardly come into contact with the etching solution, and thus these connected portions of the metal films 23 are left. Consequently, the upper and lower surfaces of the outer peripheral ends of the quartz-crystal oscillating pieces 1 are exposed by this etching along the whole peripheries except the portions connected with the connection support portions 33.

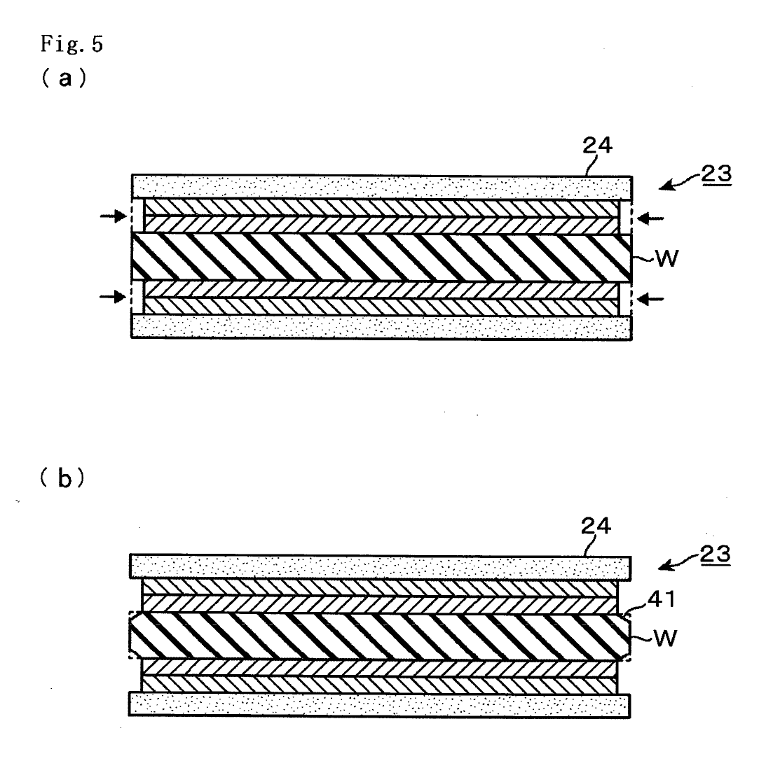

The upper and lower surfaces of the outer peripheral ends of the quartz-crystal oscillating pieces 1 are exposed by the above etching of the metal films 23, and therefore, when the wafer W is next immersed in a hydrofluoric acid aqueous solution for a predetermined time, exposed areas 42, which are areas exposed by the aforesaid etching, come into contact with the hydrofluoric acid aqueous solution. Consequently, as illustrated in FIG. 4(b), the outer peripheral ends of the quartz-crystal oscillating pieces 1 are is etched in the thickness direction by a predetermined dimension, so that, for example, tapered surfaces 41 which gradually become thinner from an inner side toward an outer side are formed. At this time, side surfaces of the quartz-crystal oscillating pieces 1 also come into contact with the hydrofluoric acid aqueous solution, but since the wafer W is the AT-cut substrate and an etching rate in the thickness direction is higher than an etching rate in a longitudinal direction (plane direction), this etching hardly progresses in a lateral direction (toward an inner side). How the tapered surfaces 41 are formed on the quartz-crystal oscillating pieces 1 as described above is illustrated in FIG. 5(a) and FIG. 5(b) which illustrate a vertical section taken along B-B line in FIG. 1. FIG. 5(a) and FIG. 5(b) correspond to FIG. 4(a) and FIG. 4(b) respectively.

Then, as illustrated in FIG. 4(c), the photoresist films 24 on the upper and lower surfaces of the wafer W are peeled off and the metal films 6, 23 are removed.

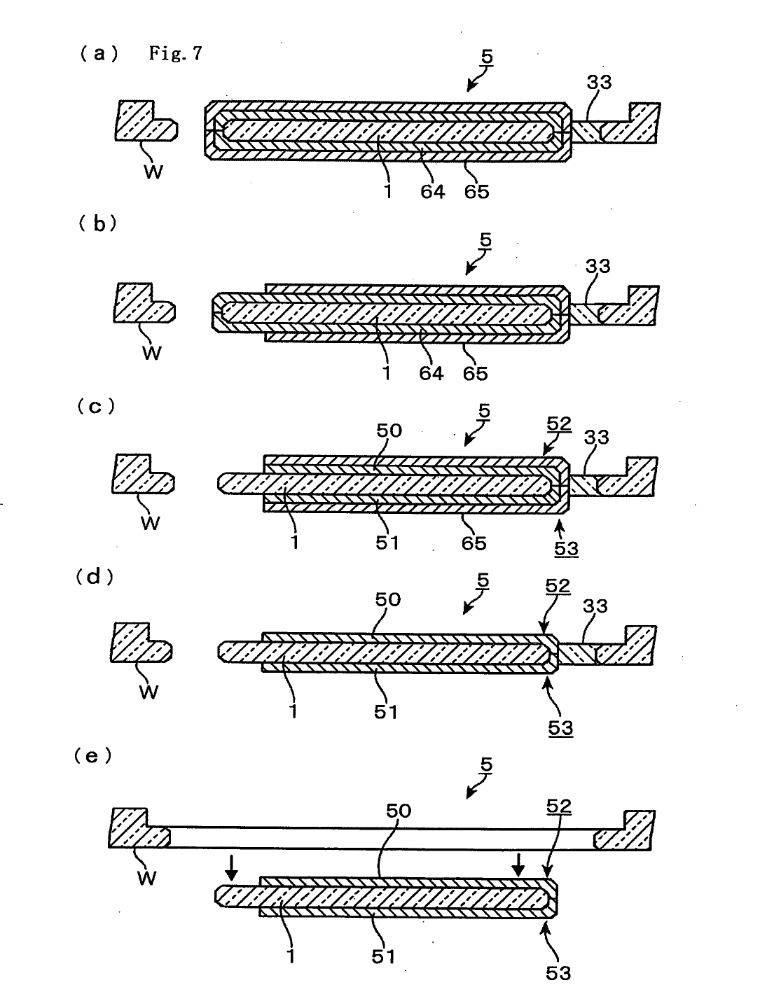

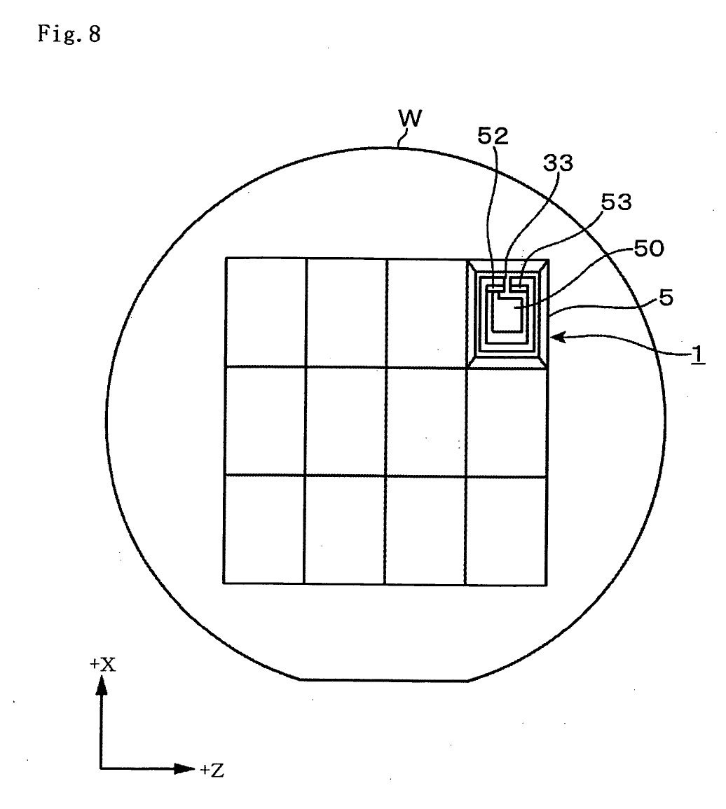

Next, processes of forming excitation electrodes 50, 51 and lead electrodes 52, 53 will be described with reference to FIG. 7(a) to FIG. 7(e). First, as illustrated in FIG. 7(a), a metal film 64 and a resist film 65 are formed on the whole surface of each of the quartz-crystal oscillating pieces 1 in this order from the wafer W side, and as illustrated in FIG. 7(b), the resist film 65 is patterned by an exposure process and a development process so as to have the shape corresponding to the electrodes 50 to 53. Next, as illustrated in FIG. 7(c), the metal film 64 is etched while the wafer W is immersed in a potassium iodide aqueous solution. By this etching, the excitation electrodes 50, 51 are formed on the upper and lower surfaces of the quartz-crystal oscillating pieces 1 respectively and the lead electrodes 52, 53 are formed so that wirings extend from the excitation electrodes 50, 51 to areas near the excitation electrodes 50, 51 on the other surface sides via a side surface on one end side (right in this example) of the quartz-crystal oscillating piece 1. Thereafter, as illustrated in FIG. 7(d), the resist film 65 is peeled off. In this manner, as illustrated in FIG. 8, the plural quartz-crystal oscillating pieces 1 connected to and supported by the connection support portions 33 are formed on the sectional areas 5 of the wafer W respectively. Then, as illustrated in FIG. 7(e), the connection support portions 33 are cut by, for example, laser dicing or the like, whereby the quartz-crystal oscillating pieces 1 in separated piece (chip) form are manufactured. In FIG. 8, the quartz-crystal oscillating piece 1 only for the single sectional area 5 is depicted, and the illustration of the quartz-crystal oscillating pieces 1 for the other sectional areas 5 is omitted.

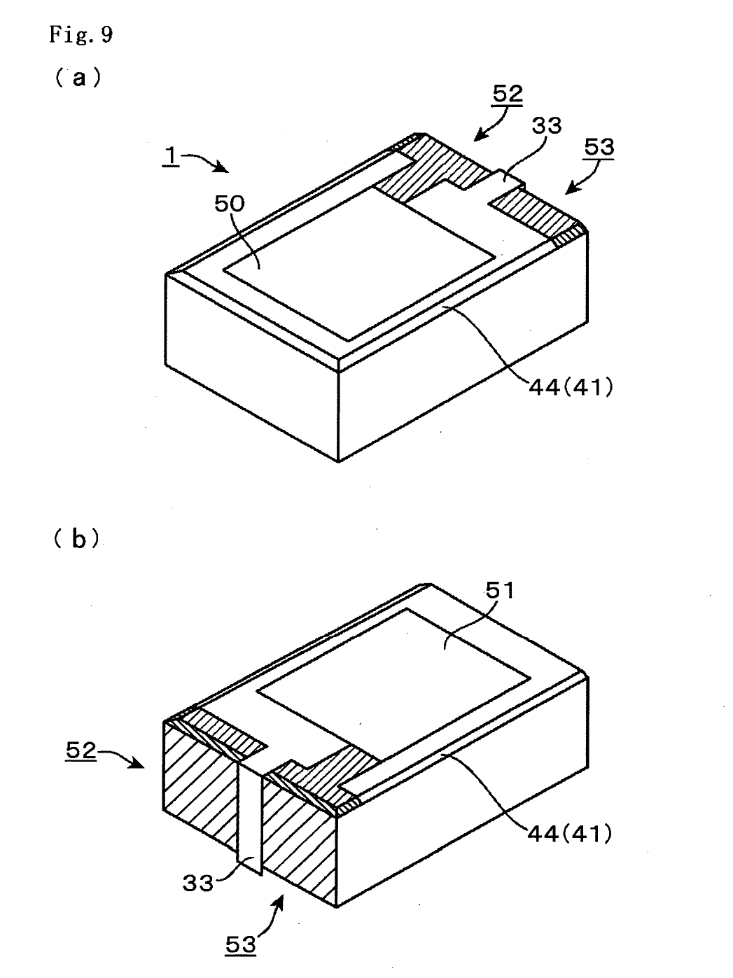

In the quartz-crystal oscillating piece 1 which is cut out (cut into a chip) from the wafer W in the above-described manner and which has a dimension of, for example, 1.000 mm×0.700 mm×50 μm (thickness) and has a weight of, for example, about 0.1 mg, beveled portions 44 (tapered surfaces 41) whose outer peripheral ends are thinner than the inner peripheral sides are formed along the whole peripheries of the upper and lower surfaces except the areas which were supported by the connection support portion 33 as illustrated in FIG. 9(a) and FIG. 9(b). In FIG. 9(a) and FIG. 9(b), 50, 51 denote the aforesaid excitation electrodes, and 52, 53 denote the lead electrodes extending from the excitation electrodes 50, 51 to the areas near the excitation electrodes 50, 51 on the other sides via the longer-side surface of the quartz-crystal oscillating piece 1. In FIG. 9(a) and FIG. 9(b), the upper surface and the lower surface of the quartz-crystal oscillating piece 1 are illustrated respectively.

According to the embodiment described above, the metal films 23 and the photoresist films 24 having the pattern with which the connection support portions 33 are formed are stacked on the wafer W in this order from the wafer W side, and the etching is performed with the photoresist films 24 and the metal films 23 used as the masks, whereby the contours of the plural quartz-crystal oscillating pieces 1 are formed in the wafer W. Then, from the direction of the through spaces 35 (side surfaces) formed by the etching for forming the contours of the quartz-crystal oscillating pieces 1, the metal films 23 are etched with the etching solution with the photoresist films 24 not being peeled off and thus left, whereby the outer peripheral sides of the metal films 23 are removed and the surfaces of the outer peripheral ends of the quartz-crystal oscillating pieces 1 are exposed, and the exposed areas 42 are etched with the etching solution in the thickness direction of the wafer W so that the outer peripheral ends of the wafer W become thinner than the inner peripheral side. Therefore, it is possible to make the outer peripheral ends of the plural quartz-crystal oscillating pieces 1 thinner than the inner peripheral sides at the wafer level, and also the process of forming the electrodes 50 to 53 which follows the process of forming the contours of the quartz-crystal oscillating pieces 1 can be performed at the wafer level. Therefore, it is possible to obtain the plural quartz-crystal oscillating pieces 1 having favorable CI values easily and at low cost.

Further, since the quartz-crystal oscillating pieces 1 can be processed at the wafer level, the processing rate does not change depending on the weight of the quartz-crystal oscillating pieces 1, and therefore, even when, for example, the quartz-crystal oscillating pieces 1 are light-weighted (small) as described above, the beveled portions 44 can be formed in a shorter time than when the beveled portions 44 are formed after the quartz-crystal oscillating pieces 1 are cut into separate pieces. Further, since the number of processes of forming the resist films (photoresist films 24) which require the exposure process, the development process, and so on can be reduced and the beveled portions 44 can be processed by a simple process of the etching with the etching solution, the processing can be easily performed with a reduced number of manhours. Furthermore, since the beveled portions 44 are processed by the etching, the processing with higher accuracy is possible than the processing utilizing the characteristic of the photoresist film as described in the aforesaid patent documents 1, 2.

Note that in FIG. 4(a) to FIG. 4(c), FIG. 5(a) and FIG. 5(b), and so on, the etched dimensions of the metal films 23 and outer peripheral ends of the quartz-crystal oscillating pieces 1 are schematically depicted larger, and the actual etched dimensions of the metal films 23 and the quartz-crystal oscillating pieces 1 are extremely small. Therefore, even when the outer peripheral sides of the metal films 23 are etched and end portions of the photoresist films 24 are not supported from the wafer W side, there is no occurrence of, for example, the peeling, chipping, and so on of the photoresist films 24.

In the above-described example, the etching of the metal films 23 from the side direction and the etching of the exposed areas 42 in the outer peripheral ends of the quartz-crystal oscillating pieces 1 are each performed once, but for example, these processes may be repeated a plurality of times, for example, twice.

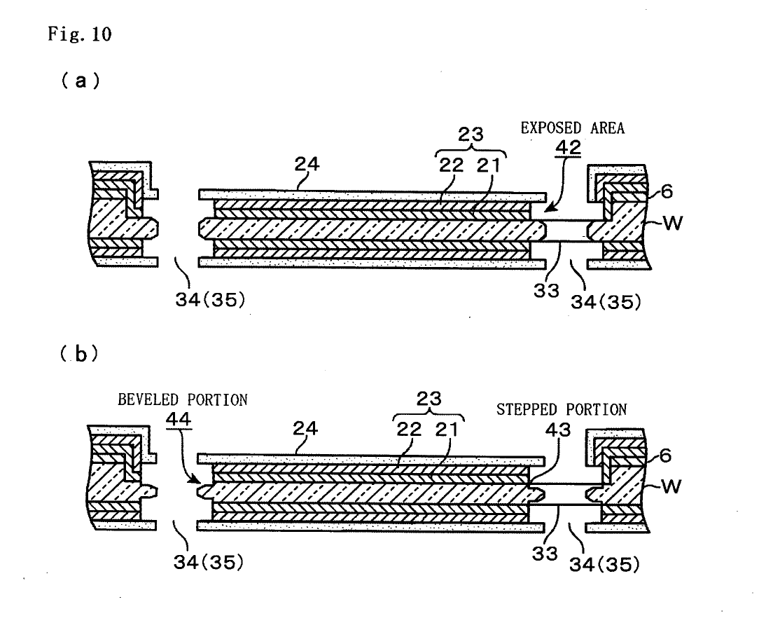

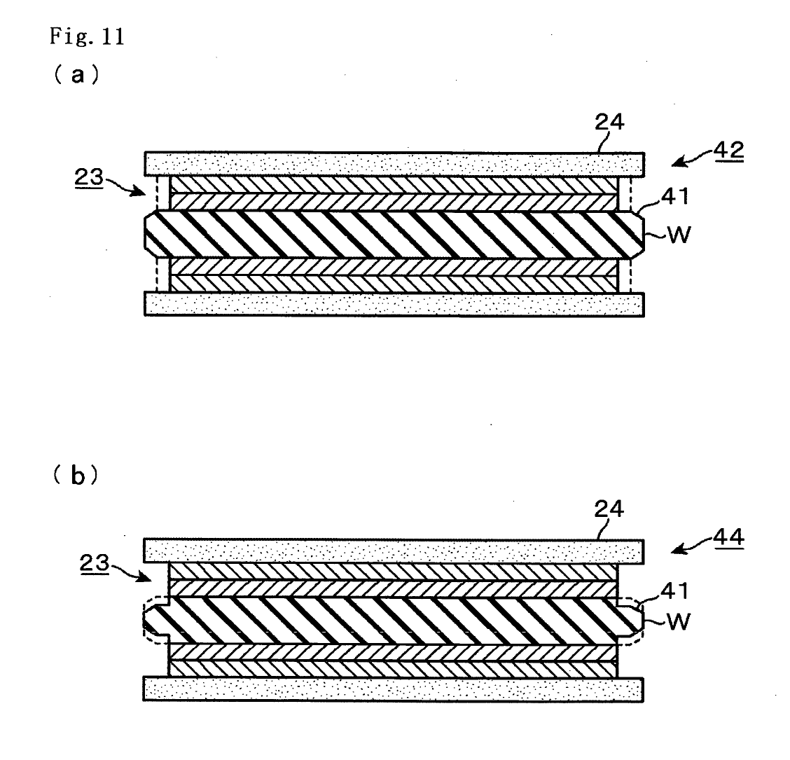

In this case, the aforesaid formation of the tapered surfaces 41 in the exposed areas 42 of the quartz-crystal oscillating pieces 1 in FIG. 4(b) (FIG. 5(b)) is followed by the process below. First, when the wafer W is immersed again in the potassium iodide aqueous solution for a predetermined time, the metal films 23 are etched from the side direction by a predetermined dimension, as illustrated in FIG. 10(a) and FIG. 11(a), and surfaces of the quartz-crystal oscillating pieces 1 which are located on a more inner side than the tapered surfaces 41 by a predetermined dimension are exposed along the whole peripheries except the portions connected with the connection support portions 33. Then, the wafer W is similarly immersed in the hydrofluoric acid aqueous solution for a predetermined time, and the exposed areas 42 including the aforesaid tapered surfaces 41 in the outer peripheral ends of the quartz-crystal oscillating pieces 1 are etched as illustrated in FIG. 10(b) and FIG. 11(b). By this processing, the exposed areas 42 of the quartz-crystal oscillating pieces 1 including the tapered surfaces 41 are etched in the thickness direction uniformly and the beveled portions 44 are formed. Consequently, between surfaces where the metal films 23 and the quartz-crystal oscillating pieces 1 are in contact with each other and the exposed areas 42, stepped portions 43 are formed, for instance.

By thus repeating the etching of the metal films 23 from the side direction and the etching of the exposed areas 42 in the outer peripheral ends of the quartz-crystal oscillating pieces 1 twice without peeling off the photoresist films 24, it is possible to further thin the outer peripheral ends of the quartz-crystal oscillating pieces 1.

At this time, these etching processes may be repeated twice or more, and the number of times these etching processes are repeated (the shape of the beveled portions 44) is appropriately set according to, for example, the dimension (thickness dimension and the outside dimension) of the quartz-crystal oscillating pieces or the frequency used for the quartz-crystal oscillating pieces. Note that FIG. 10(a) and FIG. 10(b) illustrate a vertical section taken along A-A line in FIG. 1, and FIG. 11(a) and FIG. 11(b) illustrate a vertical section taken along B-B line in FIG. 1.

The above-described example describes how the tapered surfaces 41 and the stepped portions 43 are formed in the outer peripheral ends (beveled portions 44) of the quartz-crystal oscillating pieces 1, but the shape of the outer peripheral ends sometimes differ depending on an etching condition and a plane direction of the wafer W used, and it is only necessary that the beveled portions 44 whose outer peripheral ends are thinner than the inner side are formed, and instead of the inclined surface (tapered surface 41) and the vertical surface (stepped portion 43), an R surface or the like may be adopted, for example.

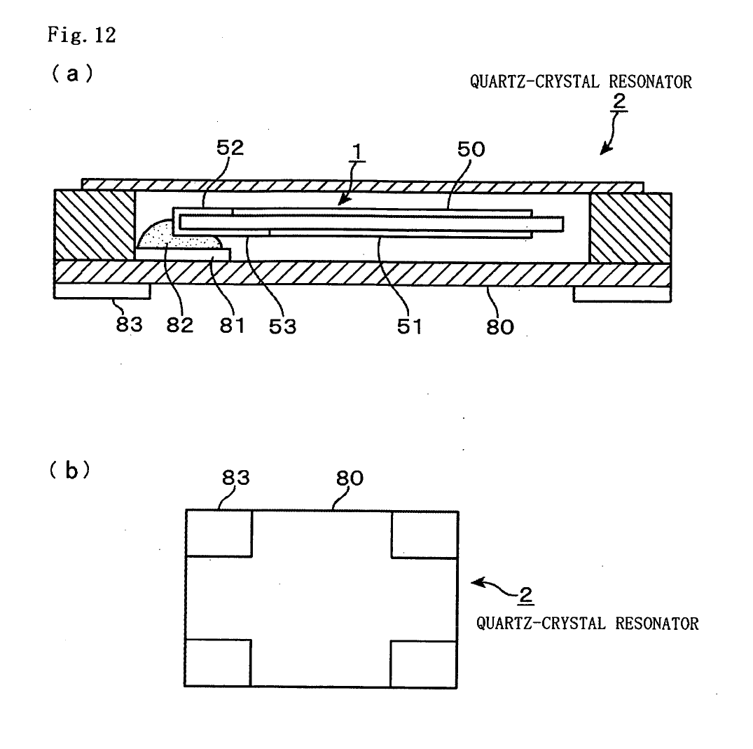

Next, a quartz-crystal unit 2 including the above-described quartz-crystal oscillating piece 1 will be described with reference to FIG. 12(a) and FIG. 12(b). In FIG. 12(a) and FIG. 12(b), 80 denotes an outer housing (vessel) housing the quartz-crystal oscillating piece 1, and 81 denotes a pair of electrodes provided at one end side in the outer housing 80. In the outer housing 80, the quartz-crystal oscillating piece 1 is fixed in a manner that the electrodes 81, 81 and the lead electrodes 52, 53 are electrically connected to each other by, for example, a conductive adhesive 82. Outer electrodes 83 formed on a lower surface of the outer housing 80 are electrically connected to the electrodes 81 to be connected to electrodes of an electronic device (electronic component) not illustrated, for instance.

1. A method of manufacturing piezoelectric oscillating pieces, comprising:
forming a metal film on a surface of a piezoelectric substrate which is cut in a manner that an etching rate in a thickness direction becomes higher than an etching rate in a plane direction;
forming a photoresist film on a surface of the metal film, the photoresist film having a pattern with which areas around the piezoelectric oscillating pieces are etched and connection support portions supporting the piezoelectric oscillating pieces are formed between the piezoelectric oscillating pieces and the piezoelectric substrate;
etching the metal film by using the photoresist film as a mask, to form a pattern by;
next, etching the piezoelectric substrate by using the photoresist film and the metal film as masks, to form contours of the piezoelectric oscillating pieces corresponding to the pattern on the piezoelectric substrate;
subsequently, from a direction of through spaces formed by the etching for forming the contours of the piezoelectric oscillating pieces, etching the metal film with an etching solution without peeling off the photoresist film, to remove outer peripheral sides of the metal film and expose surfaces of outer peripheral ends of the piezoelectric oscillating pieces; and
thereafter, etching the exposed surfaces of the piezoelectric substrate with an etching solution in the thickness direction of the piezoelectric substrate so as to make the outer peripheral ends of the piezoelectric oscillating pieces thinner than inner peripheral sides of the piezoelectric oscillating pieces.

2. The method of manufacturing the piezoelectric oscillating pieces according to claim 1, wherein the exposing the surfaces of the outer peripheral ends of the piezoelectric oscillating pieces and the etching are repeated at least once after the etching.

3. The method of manufacturing the piezoelectric oscillating pieces according to claim 1, further comprising after the etching:
forming electrodes on surfaces of the piezoelectric oscillating pieces by peeling off the photoresist film and the metal film; and
obtaining the plural piezoelectric oscillating pieces from the piezoelectric substrate by removing the connection support portions.

4. The method of manufacturing the piezoelectric oscillating pieces according to claim 1, wherein the piezoelectric substrate is an AT-cut quartz-crystal substrate.

5. A piezoelectric oscillating piece made by the method according to claim 1.

6. A piezoelectric unit comprising:
the piezoelectric oscillating piece according to claim 1;
a vessel housing the piezoelectric oscillating piece; and
an external electrode electrically connected to the electrode of the piezoelectric oscillating piece.

7. The method of manufacturing the piezoelectric oscillating pieces according to claim 2, further comprising after the etching:
forming electrodes on surfaces of the piezoelectric oscillating pieces by peeling off the photoresist film and the metal film; and
obtaining the plural piezoelectric oscillating pieces from the piezoelectric substrate by removing the connection support portions.

8. The method of manufacturing the piezoelectric oscillating pieces according to claim 2, wherein the piezoelectric substrate is an AT-cut quartz-crystal substrate.

9. The method of manufacturing the piezoelectric oscillating pieces according to claim 3, wherein the piezoelectric substrate is an AT-cut quartz-crystal substrate.

10. A piezoelectric oscillating piece made by the method according to claim 2.

11. A piezoelectric oscillating piece made by the method according to claim 3.

12. A piezoelectric oscillating piece made by the method according to claim 4.

13. A piezoelectric unit comprising:
the piezoelectric oscillating piece made by the method according to any one of claims 1 to 4 and 7 to 9;
a vessel housing the piezoelectric oscillating piece; and
an external electrode electrically connected to the electrode of the piezoelectric oscillating piece.

14. A piezoelectric unit comprising:
the piezoelectric oscillating piece according to any one of claims 5 and 10 to 12;
a vessel housing the piezoelectric oscillating piece; and
an external electrode electrically connected to the electrode of the piezoelectric oscillating piece.
